(19) United States
(12) Patent Application Publication
(10) Pub. No.: US 2022/0221743 A1
(43) Pub. Date: Jul. 14, 2022

(54) TECHNOLOGIES FOR TERMINATION FOR MICRORING MODULATORS

(71) Applicant: Intel Corporation, Santa Clara, CA (US)

(72) Inventors: Sanjeev Gupta, Santa Rosa, CA (US); Olufemi I. Dosunmu, San Jose, CA (US); Nikolai Fediakine, Mountain View, CA (US); Jin Hong, Saratoga, CA (US); David Chak Wang Hui, Santa Clara, CA (US); Christian Malouin, San Jose, CA (US); Meer Nazmus Sakib, Berkeley, CA (US); Jianying Zhou, Dublin, CA (US)

(73) Assignee: Intel Corporation, Santa Clara, CA (US)

(21) Appl. No.: 17/711,922

(22) Filed: Apr. 1, 2022

(51) Int. Cl. G02F 1/025; G02F 1/01

(52) U.S. Cl. CPC G02F 1/025; G02F 1/0121

(57) ABSTRACT

Techniques for termination for microring modulators are disclosed. In the illustrative embodiment, a microring modulator on a photonic integrated circuit (PIC) die is modulated by radiofrequency (RF) signals connected to electrodes across the microring modulator. A resistor is connected to each of the electrodes. The resistors both provide termination for the RF signals, preventing or reducing reflections, as well as forming part of a bias tee, allowing for a DC bias voltage to be applied across the electrodes.

### BACKGROUND

Silicon photonics technology is used for high-data-rate transmitter modules. Modulators using Mach-Zehnder interferometers are a common choice for silicon photonics. However, Mach-Zehnder interferometers have certain drawbacks, such as relatively high power consumption and a large footprint.

Microring modulators are a competing technology to modulators using Mach-Zehnder interferometers. Microring modulators can have high efficiency, compact size, and low power consumption.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

FIG. 1 illustrates an embodiment of a computing system including an interconnect architecture.

FIG. 2 illustrates an embodiment of an interconnect architecture including a layered stack.

FIG. 3 illustrates an embodiment of a transmitter and receiver pair for an interconnect architecture.

FIG. 4 illustrates a simplified diagram of one embodiment of a microring modulator.

FIG. 5 illustrates a cross-sectional view of the microring modulator of FIG. 4.

FIG. 6 illustrates a simplified diagram of one embodiment of a system with a microring resonator.

FIG. 7 illustrates a simplified circuit diagram corresponding to the system of FIG. 6.

FIG. 8 illustrates a simplified diagram of one embodiment of a system with a microring resonator.

FIG. 9 illustrates a simplified circuit diagram corresponding to the system of FIG. 8.

FIG. 10 illustrates a graph illustrating a simulated performance of one embodiment of a microring modulator.

FIG. 11 illustrates a graph illustrating a simulated performance of one embodiment of a microring modulator.

FIG. 12 illustrates an embodiment of a block diagram for a computing system including a multicore processor.

FIG. 13 illustrates an embodiment of a block for a computing system including multiple processors.

### DETAILED DESCRIPTION OF THE DRAWINGS

Microring modulators in a silicon photonic integrated circuit can modulate an optical signal at high rates, exceeding 100 gigabits per second. However, a microring modulator at the end of a transmission line typically reflects the incoming signal due to the capacitive nature of the microring. In order to manage the reflection, the driver must be very close to the microring resonator and/or a digital signal processor must use one or more finite impulse response filters. Such approaches limit the location of the microring resonator on the photonic integrated circuit die as well as the distance from the driver and the photonic integrated circuit die.

In the illustrative embodiment, a resistor is integrated into a photonic integrated circuit with a microring resonator. The resistor terminates the time-varying signal applied to the resonator. Additionally, a DC bias can be applied to the resonator through the resistor. The resistor reduces the reflection of the time-varying signal back to the source of the signal.

In the following description, numerous specific details are set forth, such as examples of specific types of processors and system configurations, specific hardware structures, specific architectural and micro architectural details, specific register configurations, specific instruction types, specific system components, specific measurements/heights, specific processor pipeline stages, and operation, etc. in order to provide a thorough understanding of the present disclosure. It will be apparent, however, to one skilled in the art that these specific details need not be employed to practice embodiments of the present disclosure. In other instances, well-known components or methods, such as specific and alternative processor architectures, specific logic circuits/code for described algorithms, specific firmware code, specific interconnect operation, specific logic configurations, specific manufacturing techniques and materials, specific compiler implementations, specific expression of algorithms in code, specific power down and gating techniques/logic and other specific operational details of a computer system haven't been described in detail in order to avoid unnecessarily obscuring embodiments of the present disclosure.

Although the following embodiments may be described with reference to energy conservation and energy efficiency in specific integrated circuits, such as in computing platforms or microprocessors, other embodiments are applicable to other types of integrated circuits and logic devices. Similar techniques and teachings of embodiments described herein may be applied to other types of circuits or semiconductor devices that may also benefit from better energy efficiency and energy conservation. For example, the disclosed embodiments are not limited to desktop computer systems or Ultrabooks™ and may also be used in other devices, such as handheld devices, tablets, other thin notebooks, systems on a chip (SOC) devices, and embedded applications. Some examples of handheld devices include cellular phones, Internet protocol devices, digital cameras, personal digital assistants (PDAs), and handheld PCs. Embedded applications typically include a microcontroller, a digital signal processor (DSP), a system on a chip, network computers (NetPC), set-top boxes, network hubs, wide area network (WAN) switches, or any other system that can perform the functions and operations taught below. Moreover, the apparatus', methods, and systems described herein are not limited to physical computing devices but may also relate to software optimizations for energy conservation and efficiency. As will become readily apparent in the description below, the embodiments of methods, apparatus', and systems described herein (whether in reference to hardware, firmware, software, or a combination thereof) are vital to a ‘green technology’ future balanced with performance considerations.

As computing systems are advancing, the components therein are becoming more complex. As a result, the interconnect architecture to couple and communicate between the components is also increasing in complexity to ensure bandwidth requirements are met for optimal component operation. Furthermore, different market segments demand different aspects of interconnect architectures to suit the market's needs. For example, servers require higher performance, while the mobile ecosystem is sometimes able to sacrifice overall performance for power savings. Yet, it's a singular purpose of most fabrics to provide highest possible performance with maximum power saving. Below, a number of interconnects are discussed, which would potentially benefit from aspects of the present disclosure.

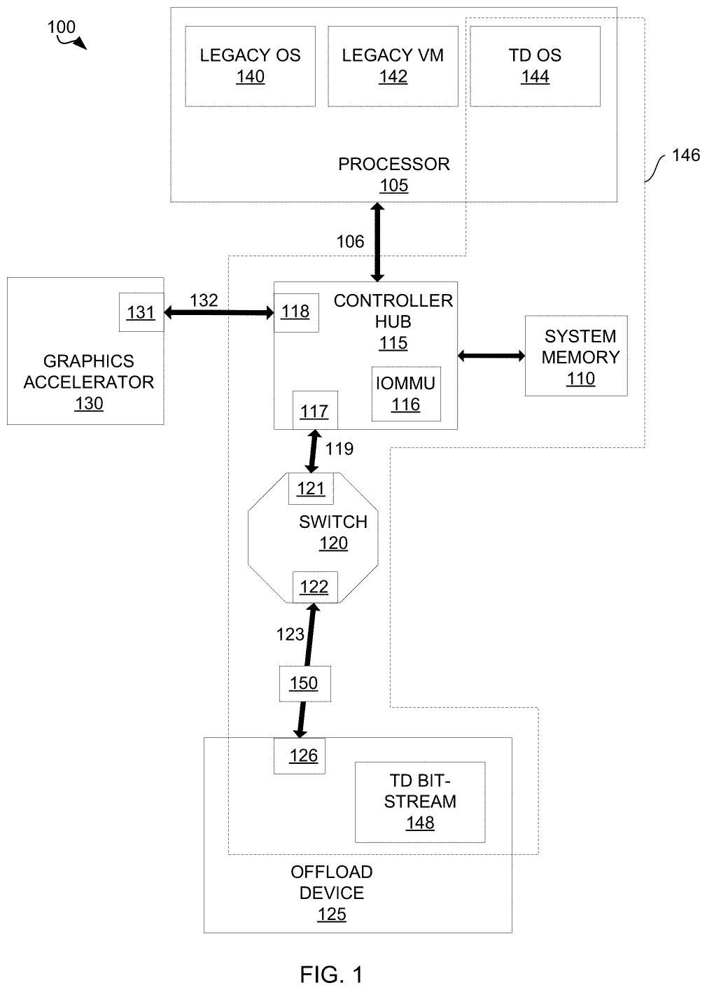

Referring to FIG. 1, an embodiment of a fabric composed of point-to-point links that interconnect a set of components is illustrated. System 100 includes processor 105, controller hub 115, and system memory 110 coupled to controller hub 115. Processor 105 includes any processing element, such as a microprocessor, a host processor, an embedded processor, a co-processor, or other processor. Processor 105 is coupled to controller hub 115 through front-side buses (FSB) 106. It should be appreciated that, in some embodiments, the computing system 100 may include more than one processor. In computing systems 100 with more processors, each pair of processors may be connected by a link. In one embodiment, FSB 106 is a serial point-to-point interconnect as described below. In another embodiment, link 106 includes a serial, differential interconnect architecture that is compliant with different interconnect standard, such as a Quick Path Interconnect (QPI) or an Ultra Path Interconnect (UPI). In some implementations, the system may include logic to implement multiple protocol stacks and further logic to negotiation alternate protocols to be run on top of a common physical layer, among other example features.

System memory 110 includes any memory device, such as random access memory (RAM), non-volatile (NV) memory, or other memory accessible by devices in system 100. In the illustrative embodiment, the system memory 110 is coupled to the controller hub 115. Additionally or alternatively, in some embodiments, the system memory 110 is coupled to processor 105 though a memory interface. Examples of a memory interface include a double-data rate (DDR) memory interface, a dual-channel DDR memory interface, and a dynamic RAM (DRAM) memory interface.

In one embodiment, controller hub 115 is a root hub, root complex, or root controller in a Compute Express Link (CXL) or Peripheral Component Interconnect Express (PCIe or PCIE) interconnection hierarchy. Examples of controller hub 115 include a chipset, a memory controller hub (MCH), a northbridge, an interconnect controller hub (ICH) a southbridge, and a root controller/hub. Often the term chipset refers to two physically separate controller hubs, i.e. a memory controller hub (MCH) coupled to an interconnect controller hub (ICH). Note that current systems often include the MCH integrated with processors 105, while controller 115 is to communicate with I/O devices, in a similar manner as described below. In some embodiments, peer-to-peer routing is optionally supported through root complex 115. In some embodiments, some or all of the controller hub 115 may be integrated with the processor 105.

The controller hub 115 also includes an input/output memory management unit (IOMMU) 116. In some embodiments, the IOMMU 116 may be referred to as a translation agent. In the illustrative embodiment, the IOMMU 116 forms part of the controller hub 115. Additionally or alternatively, in some embodiments, some or all of the IOMMU 116 may be a separate component from the controller hub 115. The IOMMU 116 can include hardware circuitry, software, or a combination of hardware and software. The IOMMU 116 can be used to provide address translation services (ATS) for address spaces in the memory 110 to allow one or more of the offload devices 135 to perform memory transactions to satisfy job requests issued by the host system.

Here, controller hub 115 is coupled to switch/bridge 120 through serial link 119. Input/output modules 117, 121, and 122, which may also be referred to as interfaces/ports 117, 121, and 122 include/implement a layered protocol stack to provide communication between controller hub 115 and switch 120. In one embodiment, multiple devices are capable of being coupled to switch 120. In some embodiments, the port 117 may be referred to as a root port 117.

Switch/bridge 120 routes packets/messages from offload device 125 upstream, i.e., up a hierarchy towards a root complex, to controller hub 115 and downstream, i.e., down a hierarchy away from a root controller, from processor 105 or system memory 110 to offload device 125. Switch 120, in one embodiment, is referred to as a logical assembly of multiple virtual PCI-to-PCI bridge devices. Offload device 125 includes an input/output module 126, which may also be referred to as an interface 126 or port 126. Offload device 125 includes any internal or external device or component to be coupled to an electronic system, such as an I/O device, a Network Interface Controller (NIC), an add-in card, an audio processor, a network processor, a hard-drive, a storage device, a CD/DVD ROM, a monitor, a printer, a mouse, a keyboard, a router, a portable storage device, a Firewire device, a Universal Serial Bus (USB) device, a scanner, an accelerator device, a field programmable gate array (FPGA), an application specific integrated circuit, and other input/output devices. Often in the PCIe vernacular, such as device, is referred to as an endpoint. Although not specifically shown, offload device 125 may include a PCIe to PCI/PCI-X bridge to support legacy or other version PCI devices. Endpoint devices in PCIe are often classified as legacy, PCIe, or root complex integrated endpoints.

Graphics accelerator 130 is also coupled to controller hub 115 through serial link 132. In one embodiment, graphics accelerator 130 is coupled to an MCH, which is coupled to an ICH. Switch 120, and accordingly offload device 125, is then coupled to the ICH. I/O modules 131 and 118 are also to implement a layered protocol stack to communicate between graphics accelerator 130 and controller hub 115. Similar to the MCH discussion above, a graphics controller or the graphics accelerator 130 itself may be integrated in processor 105. Further, one or more links (e.g., 123) of the system can include one or more extension devices (e.g., 150), such as retimers, repeaters, etc.

In the illustrative embodiment, a trusted domain 146 is established the covers a trusted domain operating system (TD OS) 144 on the processor 105 as well as a trusted domain bit-stream 148 on the offload device 125. The illustrative system 100 allows a trusted domain 144 running on the processor 105 to expand the trusted domain 144 into other XPU devices, such as a graphics processing unit (GPU), a field-programmable gate array (FPGA), an accelerator, a smart network interface controller (NIC), etc. In the illustrative embodiment, the XPU device may be embodied as or otherwise included in an offload device 125. The trusted domain can be expanded to include additional hardware, shrunk to include less hardware, merge with another trusted domain, or be split into two or more trusted domains. Trusted domains provides the capability for cloud service providers to offer secure virtual machine isolation to end users or software-as-a-service providers on the cloud. As trusted domains can be expanded and contracted on demand, an expanded domain can be used to handle events such as end of month or quarter spikes.

A trusted and secured protocol provide interfaces and logic to (1) create a compute instantiation (e.g., a bit-stream) to trusted domain of a processor 105, (2) associate XPU resources with the trusted domain, and (3) provide the trusted domain of the processor 105 access to the XPU resources. In order to perform that functionality securely, there must be an attestation flow or root of trust in order to have the processor 105 and XPU trust each other. In some embodiments, the trusted domain OS 144 can exist alongside a legacy OS 140 and/or a legacy virtual machine 142.

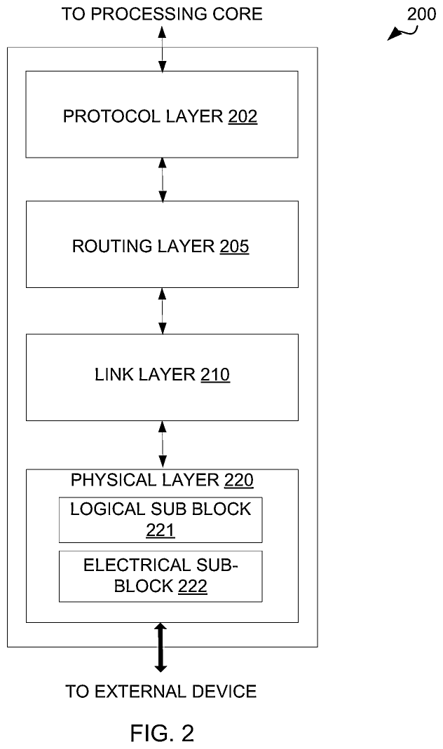

Turning to FIG. 2 an embodiment of a layered protocol stack is illustrated. Layered protocol stack 200 includes any form of a layered communication stack, such as a Quick Path Interconnect (QPI) stack, an Ultra Path Interconnect (UPI) stack, a PCIe stack, a Compute Express Link (CXL), a next generation high performance computing interconnect stack, or other layered stack. Although the discussion immediately below in reference to FIGS. 1-3 are in relation to a UPI stack, the same concepts may be applied to other interconnect stacks. In one embodiment, protocol stack 200 is a UPI protocol stack including protocol layer 202, routing layer 205, link layer 210, and physical layer 220. An interface or link, such as link 109 in FIG. 1, may be represented as communication protocol stack 200. Representation as a communication protocol stack may also be referred to as a module or interface implementing/including a protocol stack.

UPI uses packets to communicate information between components. Packets are formed in the Protocol Layer 202 to carry the information from the transmitting component to the receiving component. As the transmitted packets flow through the other layers, they are extended with additional information necessary to handle packets at those layers. At the receiving side the reverse process occurs and packets get transformed from their Physical Layer 220 representation to the Data Link Layer 210 representation and finally to the form that can be processed by the Protocol Layer 202 of the receiving device.

Protocol Layer

In one embodiment, protocol layer 202 is to provide an interface between a device's processing core and the interconnect architecture, such as data link layer 210 and physical layer 220. In this regard, a primary responsibility of the protocol layer 202 is the assembly and disassembly of packets. The packets may be categorized into different classes, such as home, snoop, data response, non-data response, non-coherent standard, and non-coherent bypass.

Routing Layer

The routing layer 205 may be used to determine the course that a packet will traverse across the available system interconnects. Routing tables may be defined by firmware and describe the possible paths that a packet can follow. In small configurations, such as a two-socket platform, the routing options are limited and the routing tables quite simple. For larger systems, the routing table options may be more complex, giving the flexibility of routing and rerouting traffic.

Link Layer

Link layer 210, also referred to as data link layer 210, acts as an intermediate stage between protocol layer 202 and the physical layer 220. In one embodiment, a responsibility of the data link layer 210 is providing a reliable mechanism for exchanging packets between two components. One side of the data link layer 210 accepts packets assembled by the protocol layer 202, applies an error detection code, i.e., CRC, and submits the modified packets to the physical layer 220 for transmission across a physical to an external device. In receiving packets, the data link layer 210 checks the CRC and, if an error is detected, instructs the transmitting device to resend. In the illustrative embodiment, CRC are performed at the flow control unit (flit) level rather than the packet level. In the illustrative embodiment, each flit is 80 bits. In other embodiments, each flit may be any suitable length, such as 16, 20, 32, 40, 64, 80, or 128 bits.

Physical Layer

In one embodiment, physical layer 220 includes logical sub block 221 and electrical sub-block 222 to physically transmit a packet to an external device. Here, logical sub-block 221 is responsible for the “digital” functions of Physical Layer 220. In this regard, the logical sub-block includes a transmit section to prepare outgoing information for transmission by physical sub-block 222, and a receiver section to identify and prepare received information before passing it to the Link Layer 210.

Physical block 222 includes a transmitter and a receiver. The transmitter is supplied by logical sub-block 221 with symbols, which the transmitter serializes and transmits onto to an external device. The receiver is supplied with serialized symbols from an external device and transforms the received signals into a bit-stream. The bit-stream is de-serialized and supplied to logical sub-block 221. In the illustrative embodiment, the physical layer 220 sends and receives bits in groups of 20 bits, called a physical unit or phit. In some embodiments, a line coding, such as an 8b/10b transmission code or a 64b/66b transmission code, is employed. In some embodiments, special symbols are used to frame a packet with frames 223. In addition, in one example, the receiver also provides a symbol clock recovered from the incoming serial stream.

As stated above, although protocol layer 202, routing layer 205, link layer 210, and physical layer 220 are discussed in reference to a specific embodiment of a QPI protocol stack, a layered protocol stack is not so limited. In fact, any layered protocol may be included/implemented. As an example, a port/interface that is represented as a layered protocol includes: (1) a first layer to assemble packets, i.e. a protocol layer; a second layer to sequence packets, i.e. a link layer; and a third layer to transmit the packets, i.e. a physical layer. As a specific example, a common standard interface (CSI) layered protocol is utilized.

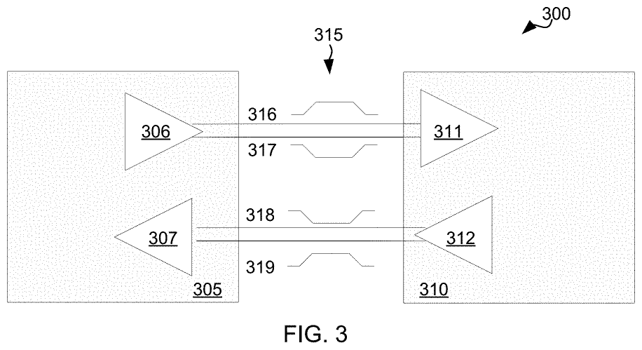

Referring next to FIG. 3, an embodiment of a UPI serial point-to-point link is illustrated. Although an embodiment of a UPI serial point-to-point link is illustrated, a serial point-to-point link is not so limited, as it includes any transmission path for transmitting serial data. In the embodiment shown, a basic UPI serial point-to-point link includes two, low-voltage, differentially driven signal pairs: a transmit pair 306/312 and a receive pair 311/307. Accordingly, device 305 includes transmission logic 306 to transmit data to device 310 and receiving logic 307 to receive data from device 310. In other words, two transmitting paths, i.e. paths 316 and 317, and two receiving paths, i.e. paths 318 and 319, are included in a UPI link.

A transmission path refers to any path for transmitting data, such as a transmission line, a copper line, an optical line, a wireless communication channel, an infrared communication link, or other communication path. A connection between two devices, such as device 305 and device 310, is referred to as a link, such as link 315. A link may support one lane—each lane representing a set of differential signal pairs (one pair for transmission, one pair for reception). To scale bandwidth, a link may aggregate multiple lanes denoted by xN, where N is any supported Link width, such as 1, 2, 4, 5, 8, 10, 12, 16, 20, 32, 64, or wider. In some implementations, each symmetric lane contains one transmit differential pair and one receive differential pair. Asymmetric lanes can contain unequal ratios of transmit and receive pairs. Some technologies can utilize symmetric lanes (e.g., UPI), while others (e.g., Displayport) may not and may even including only transmit or only receive pairs, among other examples. A link may refer to a one-way link (such as the link established by transmission logic 306 and receive logic 311) or may refer to a bi-directional link (such as the links established by transmission logic 306 and 312 and receive logic 307 and 311).

A differential pair refers to two transmission paths, such as lines 316 and 317, to transmit differential signals. As an example, when line 316 toggles from a low voltage level to a high voltage level, i.e. a rising edge, line 317 drives from a high logic level to a low logic level, i.e. a falling edge. Differential signals potentially demonstrate better electrical characteristics, such as better signal integrity, i.e. cross-coupling, voltage overshoot/undershoot, ringing, etc. This allows for better timing window, which enables faster transmission frequencies.

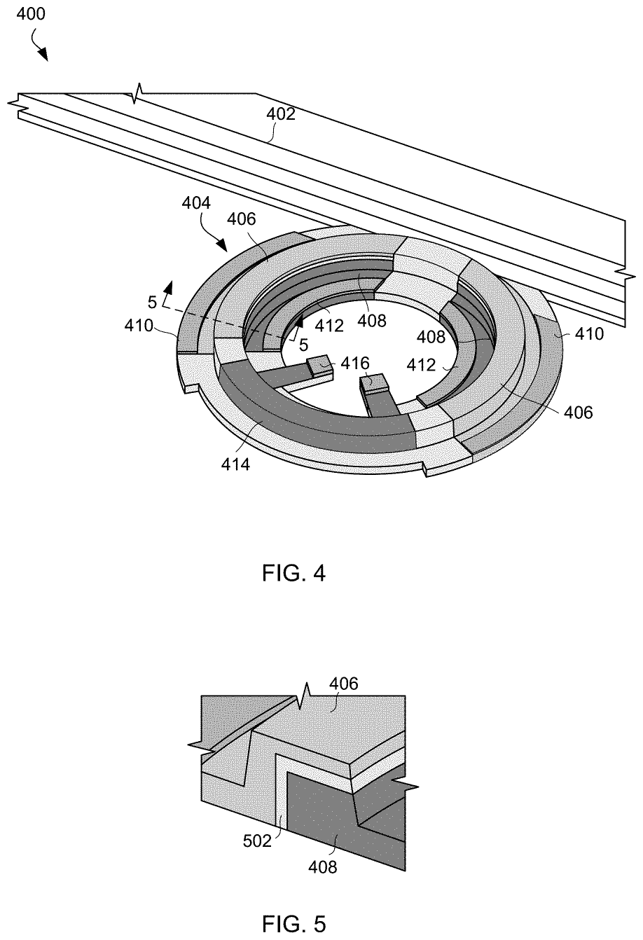

Referring now to FIG. 4, in an illustrative embodiment, a system 400 includes a waveguide 402 and a microring resonator 404. FIG. 5 shows a cross-sectional view of the system 400. The microring resonator 404 is coupled to a mode of light in the waveguide 402. In the illustrative embodiment, the microring resonator 404 has one or more n-doped portions 406 and one or more p-doped portions 408, forming one or more p-n junctions in the microring resonator. A depletion region 502 (see FIG. 5) is formed at the interface between the n-doped portion 406 and the p-doped portion 408. A bias electrode 410 is connected to each n-doped portion 406, and another bias electrode 412 is connected to each p-doped portion. A heater 414 can be used to tune the temperature of the microring resonator 404. Electrodes 416 are connected to each end of the heater 414.

In use, in the illustrative embodiment, a DC bias is applied across the bias electrode 410 and the bias electrode 412. The DC bias reverse biases the p-n junction by any suitable voltage, such as 1-5 volts. A time-varying signal is also applied across the bias electrode 410 and the bias electrode 412. The time-varying signal modulates the voltage across the p-n junction formed by the n-doped portion 406 and the p-doped portion 408, changing the electron density. The change in electron density changes the index of refraction of part of the microring resonator 404, shifting the resonance frequency. As the p-n junction is reverse biased, only a small current flows through the p-n junction. A current may be passed through the heater 414 to control the temperature of the microring resonator 404.

A light source couples light into the waveguide 402 that is at or a near a resonance of the microring resonator 404. Light that is at the resonance of the microring resonator 404 is coupled into it and lost from the waveguide 402. The time-varying signal applied to the bias electrodes 410, 412 can control the resonance of the microring resonator 404, controlling whether the light in the waveguide 402 is coupled into the microring resonator 404. As a result, the time-varying signal can modulate the light passing through the waveguide 402. The microring modulator 404 can modulate the light at any suitable rate, such as 10-50 gigahertz. The microring modulator 404 be used to send data at any suitable rate, such as 1-100 gigabits per second. The microring modulator 404 may be used with any suitable modulation, such as 2-level or 4-level pulse amplitude modulation. The voltage applied to the electrodes 410, 412 to shift the resonance of the microring resonator 404 may be any suitable voltage, such as 1-5 volts.

In the illustrative embodiment, the waveguide 402 and microring resonator 404 are made of silicon. In other embodiments, other suitable materials may be used. The waveguide 402 may be a ridge waveguide, rib waveguide, or other suitable waveguide. In the illustrative embodiment, the wavelength of the light being modulated is about 1,280 nanometers. In other embodiments, the wavelength may be any suitable wavelength, such as 1,100-1,600 nanometers.

In the illustrative embodiment, the resonator 404 is a microring with a radius of about 10 micrometers. In other embodiments, microrings with a different radius may be used, such as 5-20 micrometers. In still other embodiments, resonators other than microring resonators may be used, such as microdisk resonators, microsphere resonators, racetrack resonators, etc.

The various electrodes 410, 412, 416 may be any suitable conductive material, such as copper, polysilicon, aluminum, etc.

In the illustrative embodiment, the heater 414 forms part of the microring resonator 404. The heater 414 may be a p-doped or n-doped region with a relatively low resistance. In other embodiments, the heater 414 may be a resistor nearby the microring resonator 404 that is not part of the microring resonator 404.

In the illustrative embodiment, modulation is performed by varying the voltage across the p-n junction formed between the n-doped region 406 and the p-doped region 408. In other embodiments, modulation may be done in a different manner, such as using any suitable linear or nonlinear electrooptic effect.

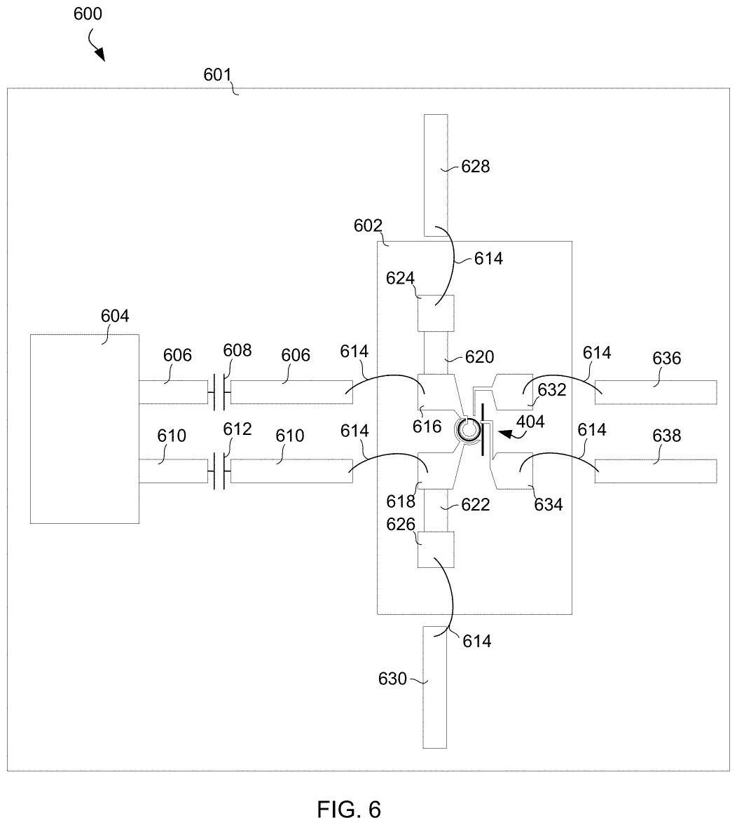

Referring now to FIG. 6, in an illustrative embodiment, a system 600 includes a circuit board 601. The circuit board 601 supports a photonic integrated circuit (PIC) die 602, which includes a microring resonator 404, such as the microring resonator 404 described above in regard to FIGS. 4 and 5. A driver 604 on the circuit board 601 is connected to the PIC die 602 by traces 606, 610 on the circuit board 601. A capacitor 608 is inline in trace 606, and another capacitor 612 is inline in trace 610. Trace 606 is connected by a wire bond 614 to a contact pad 616 on the PIC die. Similarly, trace 610 is connected by a wire bond 614 to a contact pad 618. Pad 616 forms part of or is otherwise connected to bias electrode 410, and contact pad 618 forms part of or is otherwise connected to bias electrode 412.

The PIC die 602 includes a resistor 620 between the contact pad 616 and another contact pad 624. Similarly, the PIC die 602 includes a resistor 622 between the contact pad 618 and another contact pad 626. The contact pad 624 is connected by a wire bond 614 to a trace 628 on the circuit board 601. The contact pad 626 is connected by a wire bond 614 to a trace 630 on the circuit board 601.

Two additional contact pads 632, 634 are on the PIC die 602. The contact pads 632, 634 form part of or are otherwise connected to the electrodes 416 of the heater 414. The contact pad 632 is connected by a wire bond 614 to a trace 636 on the circuit board 601, and the contact pad 634 is connected by a wire bond 614 to a trace 638 on the circuit board 601.

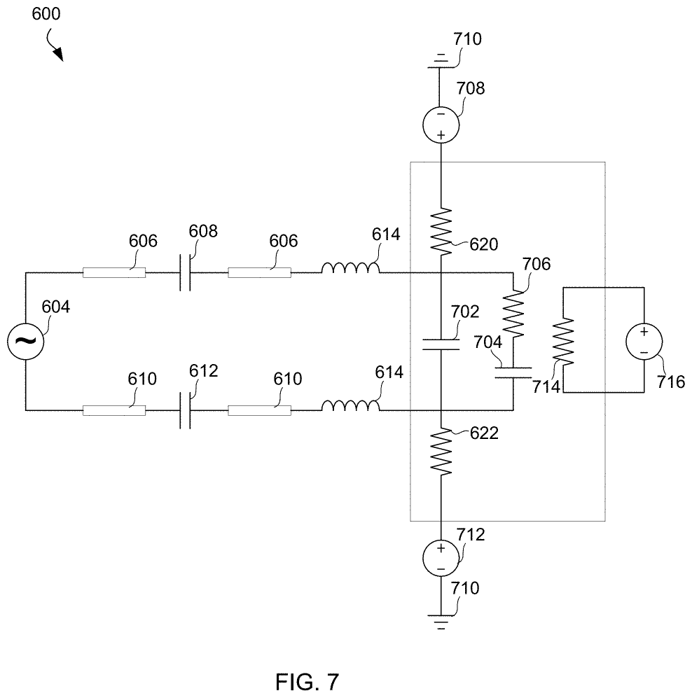

FIG. 7 shows a circuit diagram that is an approximation of the system 600 shown in FIG. 6. The driver 604 is an RF source. The wire bonds 614 connecting the traces 606, 610 to pads 616, 618 are modeled as having an inductance. The connections across the microring resonator 404 are modeled as a capacitor 702 and a resistor 706 in series with a capacitor 704, as shown in the figure. A voltage source 712 is connected to the resistor 620 and connected to ground 710. Similarly, a voltage source 708 is connected to the resistor 622 and connected to ground 710. The voltage sources 708, 712 can be used to apply a DC bias to the bias electrodes 410, 412. The heater 414 is modeled as a resistor 714 connected to a voltage supply 716.

In use, voltage is applied across pads 632, 634 to drive the heater to control the temperature of the microring resonator 404. The driver 604 sends time-varying signals to the microring resonator 404 to modulate light in the waveguide 402. The resistance of the resistors 620, 622 is chosen to match the impedance of the transmission line, resulting in the resistors 620, 622 acting as terminators and absorbing the signal sent on the traces 606, 610. As there are two resistors 620, 622, each resistor has a resistance equal to about half of the impedance of the transmission line formed by the traces 606, 610. For example, if the transmission line formed by the traces 606, 610 has an impedance of 50 Ohms, each resistor 620, 622 may have a resistance of 25 Ohms. In general, the transmission line formed by the traces 606, 610 may have any suitable impedance, such as 25-200 Ohms. Each resistor 620, 622 may have any suitable resistance, such as 10-100 Ohms.

In the illustrative embodiment, the capacitors 608, 612 act as a filter, blocking DC while passing AC signals and forming a bias tee. Radiofrequency (RF) signals are applied by the driver 604, and DC signals are applied by the pads 624, 626. The DC bias signal applied to the pads 624, 626 sets the DC voltage of the pads 616, 626 and bias electrodes 410, 412. In the illustrative embodiment, the capacitors 608, 612 are on the circuit board 601. In other embodiments, the capacitors 608, 612 may be in a different location, such as on or part of the PIC die 602.

It should be appreciated that the resistors 620, 622 have a dual purpose. First, the resistors 620, 622 will act as a wide band bias tee and provide bias to the ring modulator 404. Use of the resistors 620, 622 may reduce or eliminate the need for any other external component such as a capacitor, ferrite bead, inductor, etc., for biasing the ring modulator. Second, the same resistors 620, 622 will also serve as the RF termination to the incoming high-speed signal, reducing or minimizing the reflection from the ring modulator 404. This arrangement of resistors 620, 622 will allow use of a longer input interconnect length between the driver 604 and ring modulator 404. The resistor value can be adjusted to obtain wide band response for the RF insertion loss and good isolation between the RF and biasing ports. Since the bias tee/RF termination is purely resistive, it provides excellent wideband performance and reduces or eliminates the need for a separate bias tee and termination network.

In the illustrative embodiment, the resistors 620, 622 result in several advantages. The termination provided by the resistors 620, 622 reduces or minimizes the electrical reflections between the driver 604 and the ring modulator 404 and improves the subsystem bandwidth. As the driver 604 does not need to be particularly close to the ring modulator 404, the design of the system 600 is more tolerant towards long length of interconnect between the driver 604 and the ring modulator 404, allowing a more flexible design of the driver 604 and PIC die 602 and relaxing packaging requirements. The resistors 620, 622 provide a very wide band bias tee which can provide bias to the ring 404 from DC to 100 GHz. In embodiments with monolithically integrated resistors 620, 622, bias tee parasitic capacitance is reduced or minimized, enabling high frequency behavior. In embodiments with more than one modulator 404, the modulators 404 can be positioned on the PIC die 602 with fewer constraints, enabling biasing of high density of TX and RX channels. The design allows programmable control of biasing point control using a power management integrated circuit (PMIC). The design on the system 600 reduces bias voltage requirements to a few volts. Reduced current flow through the PIC die 602 makes the PIC die 602 more reliable. The design allows for the user of an integrated driver 604 and digital signal processor (DSP), which may reduce the cost and power consumption are compared to a discrete driver 604 and DSP.

The system 600 may be embodied as any suitable electrical component, such as a router, a switch, an interconnect, a network interface controller, a processor, a digital signal processor, an application specific integrated circuit, and/or the like. The system 600 may include components not shown in FIG. 6, such as a processor, memory, other integrated circuit components, power components, etc. In some embodiments, the system 600 may be embodied as, form part of, or include the system 100. In one embodiment, the system 600 is used in a data center to transmit data between switches, sleds, rack, etc.

The circuit board 601 may be any suitable circuit board. In one embodiment, the circuit board 601 is a fiberglass board such as FR-4. In some embodiments, the PIC die 602 and/or the driver 604 may be mounted on a component other than a circuit board 601, such as another chip or die using a flip chip technique.

The PIC die 602 may be any suitable material. In the illustrative embodiment, the PIC die 602 is made of silicon. The PIC die 602 may include other components not shown in FIG. 6, such as one or more lasers, LEDs, waveguides, photodetectors, optical fiber interfaces, etc.

In the illustrative embodiment, the resistors 620, 622 are monolithically integrated in the PIC die 602. The resistors 620, 622 may be any suitable resistor, such as a diffused resistor, an ion-implanted resistors, a thin-film resistor, or a polysilicon resistor. In other embodiments, the resistors 620, 622 may be separate components mounted on the PIC die 602.

In the illustrative embodiment, the pads 616, 618, 624, 626, 632, 634 are wire bonded to various traces 606, 610, 628, 630, 636, 638 on the board 601. In other embodiments, the pads 616, 618, 624, 626, 632, 634 may be wire bonded to other integrated circuit components, and/or the 616, 618, 624, 626, 632, 634 may be embodied as bumps connected to another component, such as in a flip chip design.

The PIC die 602 may include several microresonators 404, such as 2-1,024 microresonators 404. The system 600 may include, e.g., a pair of traces 606, 610, a pair of pads 616, 618, etc., for each microresonator 404, as necessary.

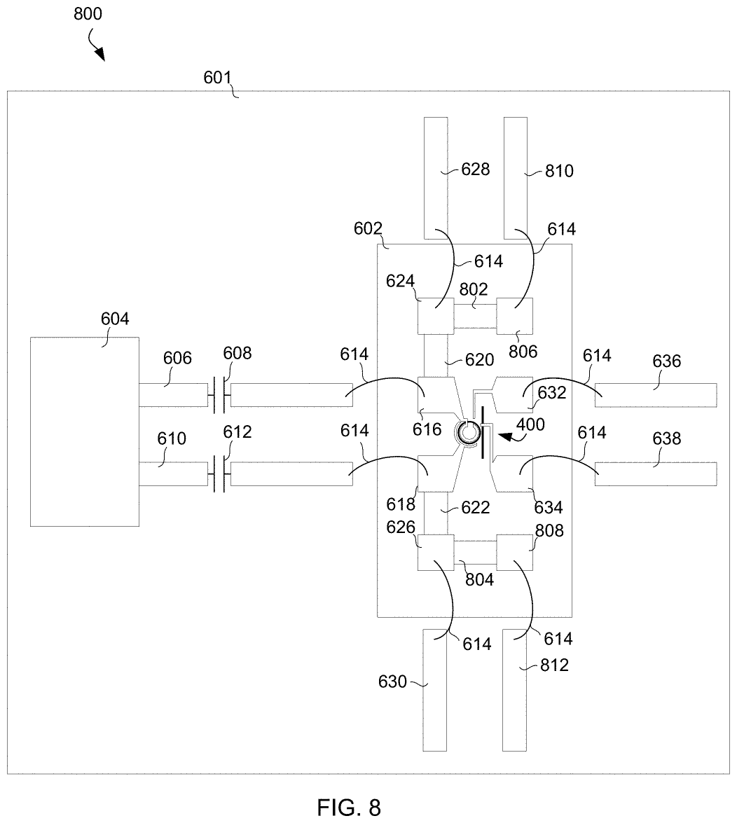

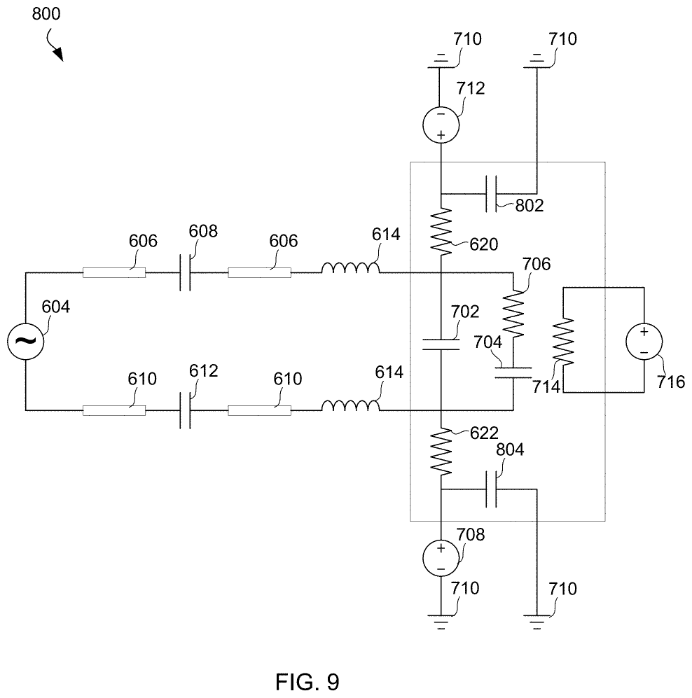

Referring now to FIG. 8, in one embodiment, a bypass capacitor 802 is connected across the pad 624 and a pad 806, in parallel with the resistor 620. A wire bond 614 connects the pad 806 to a trace 810, which is connected to ground. Similarly, a bypass capacitor 804 is connected across the pad 626 and pad 808, in parallel with the resistor 622. A wire bond 614 connects the pad 808 to a trace 812, which is connected to ground. FIG. 9 shows a circuit diagram that is an approximation of the system 600 shown in FIG. 6. Capacitors 802, 804 help reduce power supply noise and sinks high-frequency signals from the voltage sources 708 712.

In the illustrative embodiment, the capacitors 802, 804 are monolithically integrated into the PIC die 602. For example, the capacitors 802, 804 may be metal-insulator-metal (MIM) capacitors. In other embodiments, the capacitors 802, 804 may be separate components mounted on the PIC die 602.

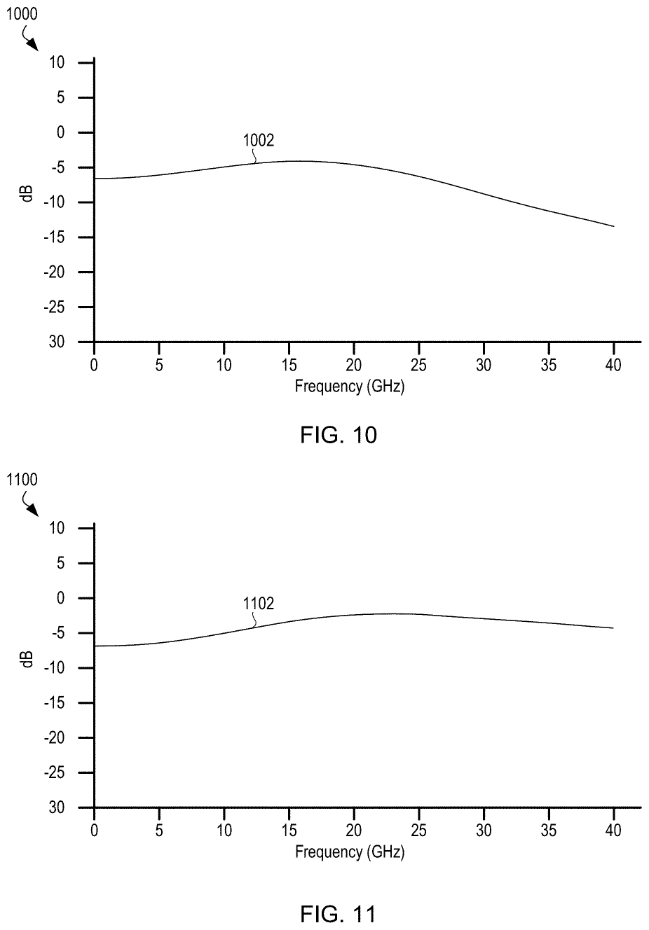

Referring now to FIGS. 10 and 11 in one embodiment, data from simulations show the performance of the system 600, 800. FIG. 10 shows a graph 1000 with a line 1002 showing the scattering parameter S(2,1) as a function of frequency. FIG. 11 shows a graph 1100 with a line 1102 showing the scattering parameter S(1,1) as a function of frequency. In this design, the termination resistors 620, 622 were optimized to achieve minimum power consumption, minimum insertion loss for the ring modulator 404, and an acceptable return loss performance. The design shows a wide band performance of the modulator 404 free from resonance even when interconnect length was more than an inch.

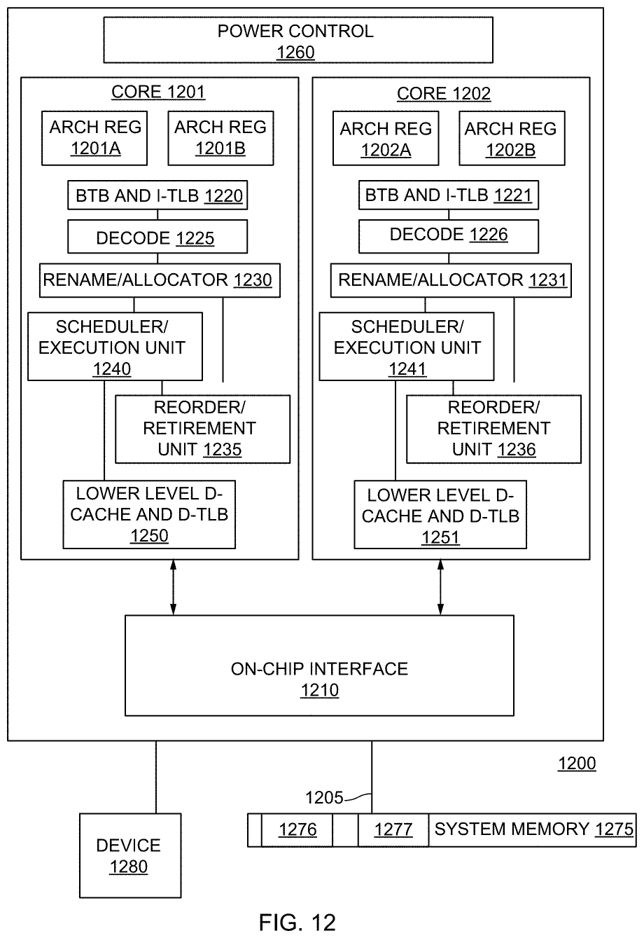

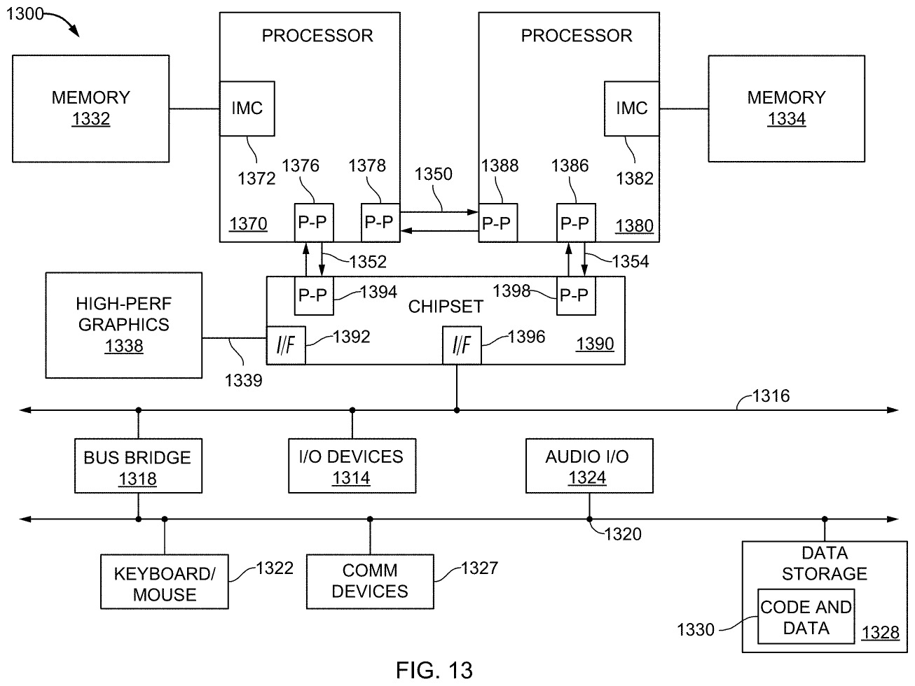

Referring to FIG. 12, an embodiment of a block diagram for a computing system including a multicore processor is depicted. Processor 1200 includes any processor or processing device, such as a microprocessor, an embedded processor, a digital signal processor (DSP), a network processor, a handheld processor, an application processor, a co-processor, a system on a chip (SOC), or other device to execute code. Processor 1200, in one embodiment, includes at least two cores—core 1201 and 1202, which may include asymmetric cores or symmetric cores (the illustrated embodiment). However, processor 1200 may include any number of processing elements that may be symmetric or asymmetric.

In one embodiment, a processing element refers to hardware or logic to support a software thread. Examples of hardware processing elements include: a thread unit, a thread slot, a thread, a process unit, a context, a context unit, a logical processor, a hardware thread, a core, and/or any other element, which is capable of holding a state for a processor, such as an execution state or architectural state. In other words, a processing element, in one embodiment, refers to any hardware capable of being independently associated with code, such as a software thread, operating system, application, or other code. A physical processor (or processor socket) typically refers to an integrated circuit, which potentially includes any number of other processing elements, such as cores or hardware threads.

A core often refers to logic located on an integrated circuit capable of maintaining an independent architectural state, wherein each independently maintained architectural state is associated with at least some dedicated execution resources. In contrast to cores, a hardware thread typically refers to any logic located on an integrated circuit capable of maintaining an independent architectural state, wherein the independently maintained architectural states share access to execution resources. As can be seen, when certain resources are shared and others are dedicated to an architectural state, the line between the nomenclature of a hardware thread and core overlaps. Yet often, a core and a hardware thread are viewed by an operating system as individual logical processors, where the operating system is able to individually schedule operations on each logical processor.

Physical processor 1200, as illustrated in FIG. 12, includes two cores—core 1201 and 1202. Here, core 1201 and 1202 are considered symmetric cores, i.e. cores with the same configurations, functional units, and/or logic. In another embodiment, core 1201 includes an out-of-order processor core, while core 1202 includes an in-order processor core. However, cores 1201 and 1202 may be individually selected from any type of core, such as a native core, a software managed core, a core adapted to execute a native Instruction Set Architecture (ISA), a core adapted to execute a translated Instruction Set Architecture (ISA), a co-designed core, or other known core. In a heterogeneous core environment (i.e. asymmetric cores), some form of translation, such a binary translation, may be utilized to schedule or execute code on one or both cores. Yet to further the discussion, the functional units illustrated in core 1201 are described in further detail below, as the units in core 1202 operate in a similar manner in the depicted embodiment.

As depicted, core 1201 includes two hardware threads 1201a and 1201b, which may also be referred to as hardware thread slots 1201a and 1201b. Therefore, software entities, such as an operating system, in one embodiment potentially view processor 1200 as four separate processors, i.e., four logical processors or processing elements capable of executing four software threads concurrently. As alluded to above, a first thread is associated with architecture state registers 1201a, a second thread is associated with architecture state registers 1201b, a third thread may be associated with architecture state registers 1202a, and a fourth thread may be associated with architecture state registers 1202b. Here, each of the architecture state registers (1201a, 1201b, 1202a, and 1202b) may be referred to as processing elements, thread slots, or thread units, as described above. As illustrated, architecture state registers 1201a are replicated in architecture state registers 1201b, so individual architecture states/contexts are capable of being stored for logical processor 1201a and logical processor 1201b. In core 1201, other smaller resources, such as instruction pointers and renaming logic in allocator and renamer block 1230 may also be replicated for threads 1201a and 1201b. Some resources, such as re-order buffers in reorder/retirement unit 1235, ILTB 1220, load/store buffers, and queues may be shared through partitioning. Other resources, such as general purpose internal registers, page-table base register(s), low-level data-cache and data-TLB 1215, execution unit(s) 1240, and portions of out-of-order unit 1235 are potentially fully shared.

Processor 1200 often includes other resources, which may be fully shared, shared through partitioning, or dedicated by/to processing elements. In FIG. 12, an embodiment of a purely exemplary processor with illustrative logical units/resources of a processor is illustrated. Note that a processor may include, or omit, any of these functional units, as well as include any other known functional units, logic, or firmware not depicted. As illustrated, core 1201 includes a simplified, representative out-of-order (OOO) processor core. But an in-order processor may be utilized in different embodiments. The OOO core includes a branch target buffer 1220 to predict branches to be executed/taken and an instruction-translation buffer (I-TLB) 1220 to store address translation entries for instructions.

Core 1201 further includes decode module 1225 coupled to fetch unit 1220 to decode fetched elements. Fetch logic, in one embodiment, includes individual sequencers associated with thread slots 1201a, 1201b, respectively. Usually core 1201 is associated with a first ISA, which defines/specifies instructions executable on processor 1200. Often machine code instructions that are part of the first ISA include a portion of the instruction (referred to as an opcode), which references/specifies an instruction or operation to be performed. Decode logic 1225 includes circuitry that recognizes these instructions from their opcodes and passes the decoded instructions on in the pipeline for processing as defined by the first ISA. For example, as discussed in more detail below decoders 1225, in one embodiment, include logic designed or adapted to recognize specific instructions, such as transactional instruction. As a result of the recognition by decoders 1225, the architecture or core 1201 takes specific, predefined actions to perform tasks associated with the appropriate instruction. It is important to note that any of the tasks, blocks, operations, and methods described herein may be performed in response to a single or multiple instructions; some of which may be new or old instructions. Note decoders 1226, in one embodiment, recognize the same ISA (or a subset thereof). Alternatively, in a heterogeneous core environment, decoders 1226 recognize a second ISA (either a subset of the first ISA or a distinct ISA).

In one example, allocator and renamer block 1230 includes an allocator to reserve resources, such as register files to store instruction processing results. However, threads 1201a and 1201b are potentially capable of out-of-order execution, where allocator and renamer block 1230 also reserves other resources, such as reorder buffers to track instruction results. Unit 1230 may also include a register renamer to rename program/instruction reference registers to other registers internal to processor 1200. Reorder/retirement unit 1235 includes components, such as the reorder buffers mentioned above, load buffers, and store buffers, to support out-of-order execution and later in-order retirement of instructions executed out-of-order.

Scheduler and execution unit(s) block 1240, in one embodiment, includes a scheduler unit to schedule instructions/operation on execution units. For example, a floating point instruction is scheduled on a port of an execution unit that has an available floating point execution unit. Register files associated with the execution units are also included to store information instruction processing results. Exemplary execution units include a floating point execution unit, an integer execution unit, a jump execution unit, a load execution unit, a store execution unit, and other known execution units.

Lower level data cache and data translation buffer (D-TLB) 1250 are coupled to execution unit(s) 1240. The data cache is to store recently used/operated on elements, such as data operands, which are potentially held in memory coherency states. The D-TLB is to store recent virtual/linear to physical address translations. As a specific example, a processor may include a page table structure to break physical memory into a plurality of virtual pages.

Here, cores 1201 and 1202 share access to higher-level or further-out cache, such as a second level cache associated with on-chip interface 1210. Note that higher-level or further-out refers to cache levels increasing or getting further way from the execution unit(s). In one embodiment, higher-level cache is a last-level data cache—last cache in the memory hierarchy on processor 1200—such as a second or third level data cache. However, higher level cache is not so limited, as it may be associated with or include an instruction cache. A trace cache—a type of instruction cache—instead may be coupled after decoder 1225 to store recently decoded traces. Here, an instruction potentially refers to a macro-instruction (i.e. a general instruction recognized by the decoders), which may decode into a number of micro-instructions (micro-operations).

In the depicted configuration, processor 1200 also includes on-chip interface module 1210. Historically, a memory controller, which is described in more detail below, has been included in a computing system external to processor 1200. In this scenario, on-chip interface 1210 is to communicate with devices external to processor 1200, such as system memory 1275, a chipset (often including a memory controller hub to connect to memory 1275 and an I/O controller hub to connect peripheral devices), a memory controller hub, a northbridge, or other integrated circuit. And in this scenario, bus 1205 may include any known interconnect, such as multi-drop bus, a point-to-point interconnect, a serial interconnect, a parallel bus, a coherent (e.g. cache coherent) bus, a layered protocol architecture, a differential bus, and a GTL bus.

Memory 1275 may be dedicated to processor 1200 or shared with other devices in a system. Common examples of types of memory 1275 include DRAM, SRAM, non-volatile memory (NV memory), and other known storage devices. Note that device 1280 may include a graphic accelerator, processor or card coupled to a memory controller hub, data storage coupled to an I/O controller hub, a wireless transceiver, a flash device, an audio controller, a network controller, or other known device.

Recently however, as more logic and devices are being integrated on a single die, such as SOC, each of these devices may be incorporated on processor 1200. For example in one embodiment, a memory controller hub is on the same package and/or die with processor 1200. Here, a portion of the core (an on-core portion) 1210 includes one or more controller(s) for interfacing with other devices such as memory 1275 or a graphics device 1280. The configuration including an interconnect and controllers for interfacing with such devices is often referred to as an on-core (or un-core configuration). As an example, on-chip interface 1210 includes a ring interconnect for on-chip communication and a high-speed serial point-to-point link 1205 for off-chip communication. Yet, in the SOC environment, even more devices, such as the network interface, co-processors, memory 1275, graphics processor 1280, and any other known computer devices/interface may be integrated on a single die or integrated circuit to provide small form factor with high functionality and low power consumption.

In one embodiment, processor 1200 is capable of executing a compiler, optimization, and/or translator code 1277 to compile, translate, and/or optimize application code 1276 to support the apparatus and methods described herein or to interface therewith. A compiler often includes a program or set of programs to translate source text/code into target text/code. Usually, compilation of program/application code with a compiler is done in multiple phases and passes to transform hi-level programming language code into low-level machine or assembly language code. Yet, single pass compilers may still be utilized for simple compilation. A compiler may utilize any known compilation techniques and perform any known compiler operations, such as lexical analysis, preprocessing, parsing, semantic analysis, code generation, code transformation, and code optimization.

Larger compilers often include multiple phases, but most often these phases are included within two general phases: (1) a front-end, i.e. generally where syntactic processing, semantic processing, and some transformation/optimization may take place, and (2) a back-end, i.e. generally where analysis, transformations, optimizations, and code generation takes place. Some compilers refer to a middle, which illustrates the blurring of delineation between a front-end and back end of a compiler. As a result, reference to insertion, association, generation, or other operation of a compiler may take place in any of the aforementioned phases or passes, as well as any other known phases or passes of a compiler. As an illustrative example, a compiler potentially inserts operations, calls, functions, etc. in one or more phases of compilation, such as insertion of calls/operations in a front-end phase of compilation and then transformation of the calls/operations into lower-level code during a transformation phase. Note that during dynamic compilation, compiler code or dynamic optimization code may insert such operations/calls, as well as optimize the code for execution during runtime. As a specific illustrative example, binary code (already compiled code) may be dynamically optimized during runtime. Here, the program code may include the dynamic optimization code, the binary code, or a combination thereof.

Similar to a compiler, a translator, such as a binary translator, translates code either statically or dynamically to optimize and/or translate code. Therefore, reference to execution of code, application code, program code, or other software environment may refer to: (1) execution of a compiler program(s), optimization code optimizer, or translator either dynamically or statically, to compile program code, to maintain software structures, to perform other operations, to optimize code, or to translate code; (2) execution of main program code including operations/calls, such as application code that has been optimized/compiled; (3) execution of other program code, such as libraries, associated with the main program code to maintain software structures, to perform other software related operations, or to optimize code; or (4) a combination thereof.

Referring now to FIG. 13, shown is a block diagram of another system 1300 in accordance with an embodiment of the present disclosure. As shown in FIG. 13, multiprocessor system 1300 is a point-to-point interconnect system, and includes a first processor 1370 and a second processor 1380 coupled via a point-to-point interconnect 1350. Each of processors 1370 and 1380 may be some version of a processor. In one embodiment, 1352 and 1354 are part of a serial, point-to-point coherent interconnect fabric, such as a high-performance architecture. As a result, aspects of the present disclosure may be implemented within the QPI architecture.

While shown with only two processors 1370, 1380, it is to be understood that the scope of the present disclosure is not so limited. In other embodiments, one or more additional processors may be present in a given processor.

Processors 1370 and 1380 are shown including integrated memory controller units 1372 and 1382, respectively. Processor 1370 also includes as part of its bus controller units point-to-point (P-P) interfaces 1376 and 1378; similarly, second processor 1380 includes P-P interfaces 1386 and 1388. Processors 1370, 1380 may exchange information via a point-to-point (P-P) interface 1350 using P-P interface circuits 1378, 1388. As shown in FIG. 13, IMCs 1372 and 1382 couple the processors to respective memories, namely a memory 1332 and a memory 1334, which may be portions of main memory locally attached to the respective processors.

Processors 1370, 1380 each exchange information with a chipset 1390 via individual P-P interfaces 1352, 1354 using point to point interface circuits 1376, 1394, 1386, 1398. Chipset 1390 also exchanges information with a high-performance graphics circuit 1338 via an interface circuit 1392 along a high-performance graphics interconnect 1339.

A shared cache (not shown) may be included in either processor or outside of both processors; yet connected with the processors via P-P interconnect, such that either or both processors' local cache information may be stored in the shared cache if a processor is placed into a low power mode.

Chipset 1390 may be coupled to a first bus 1316 via an interface 1396. In one embodiment, first bus 1316 may be a Peripheral Component Interconnect (PCI) bus, or a bus such as a PCI Express bus or another third generation I/O interconnect bus, although the scope of the present disclosure is not so limited.

As shown in FIG. 13, various I/O devices 1314 are coupled to first bus 1316, along with a bus bridge 1318 which couples first bus 1316 to a second bus 1320. In one embodiment, second bus 1320 includes a low pin count (LPC) bus. Various devices are coupled to second bus 1320 including, for example, a keyboard and/or mouse 1322, communication devices 1327 and a storage unit 1328 such as a disk drive or other mass storage device which often includes instructions/code and data 1330, in one embodiment. Further, an audio I/O 1324 is shown coupled to second bus 1320. Note that other architectures are possible, where the included components and interconnect architectures vary. For example, instead of the point-to-point architecture of FIG. 13, a system may implement a multi-drop bus or other such architecture.

While aspects of the present disclosure have been described with respect to a limited number of embodiments, those skilled in the art will appreciate numerous modifications and variations therefrom. It is intended that the appended claims cover all such modifications and variations as fall within the true spirit and scope of this present disclosure.

A design may go through various stages, from creation to simulation to fabrication. Data representing a design may represent the design in a number of manners. First, as is useful in simulations, the hardware may be represented using a hardware description language or another functional description language. Additionally, a circuit level model with logic and/or transistor gates may be produced at some stages of the design process. Furthermore, most designs, at some stage, reach a level of data representing the physical placement of various devices in the hardware model. In the case where conventional semiconductor fabrication techniques are used, the data representing the hardware model may be the data specifying the presence or absence of various features on different mask layers for masks used to produce the integrated circuit. In any representation of the design, the data may be stored in any form of a machine readable medium. A memory or a magnetic or optical storage such as a disc may be the machine readable medium to store information transmitted via optical or electrical wave modulated or otherwise generated to transmit such information. When an electrical carrier wave indicating or carrying the code or design is transmitted, to the extent that copying, buffering, or re-transmission of the electrical signal is performed, a new copy is made. Thus, a communication provider or a network provider may store on a tangible, machine-readable medium, at least temporarily, an article, such as information encoded into a carrier wave, embodying techniques of embodiments of the present disclosure.

A module as used herein refers to any combination of hardware, software, and/or firmware. As an example, a module includes hardware, such as a micro-controller, associated with a non-transitory medium to store code adapted to be executed by the micro-controller. Therefore, reference to a module, in one embodiment, refers to the hardware, which is specifically configured to recognize and/or execute the code to be held on a non-transitory medium. Furthermore, in another embodiment, use of a module refers to the non-transitory medium including the code, which is specifically adapted to be executed by the microcontroller to perform predetermined operations. And as can be inferred, in yet another embodiment, the term module (in this example) may refer to the combination of the microcontroller and the non-transitory medium. Often module boundaries that are illustrated as separate commonly vary and potentially overlap. For example, a first and a second module may share hardware, software, firmware, or a combination thereof, while potentially retaining some independent hardware, software, or firmware. In one embodiment, use of the term logic includes hardware, such as transistors, registers, or other hardware, such as programmable logic devices.

Use of the phrase ‘configured to,’ in one embodiment, refers to arranging, putting together, manufacturing, offering to sell, importing and/or designing an apparatus, hardware, logic, or element to perform a designated or determined task. In this example, an apparatus or element thereof that is not operating is still ‘configured to’ perform a designated task if it is designed, coupled, and/or interconnected to perform said designated task. As a purely illustrative example, a logic gate may provide a 0 or a 1 during operation. But a logic gate ‘configured to’ provide an enable signal to a clock does not include every potential logic gate that may provide a 1 or 0. Instead, the logic gate is one coupled in some manner that during operation the 1 or 0 output is to enable the clock. Note once again that use of the term ‘configured to’ does not require operation, but instead focus on the latent state of an apparatus, hardware, and/or element, where in the latent state the apparatus, hardware, and/or element is designed to perform a particular task when the apparatus, hardware, and/or element is operating.

Furthermore, use of the phrases ‘to,’ ‘capable of/to,’ and or ‘operable to,’ in one embodiment, refers to some apparatus, logic, hardware, and/or element designed in such a way to enable use of the apparatus, logic, hardware, and/or element in a specified manner. Note as above that use of to, capable to, or operable to, in one embodiment, refers to the latent state of an apparatus, logic, hardware, and/or element, where the apparatus, logic, hardware, and/or element is not operating but is designed in such a manner to enable use of an apparatus in a specified manner.

A value, as used herein, includes any known representation of a number, a state, a logical state, or a binary logical state. Often, the use of logic levels, logic values, or logical values is also referred to as 1's and 0's, which simply represents binary logic states. For example, a 1 refers to a high logic level and 0 refers to a low logic level. In one embodiment, a storage cell, such as a transistor or flash cell, may be capable of holding a single logical value or multiple logical values. However, other representations of values in computer systems have been used. For example the decimal number ten may also be represented as a binary value of 1010 and a hexadecimal letter A. Therefore, a value includes any representation of information capable of being held in a computer system.

Moreover, states may be represented by values or portions of values. As an example, a first value, such as a logical one, may represent a default or initial state, while a second value, such as a logical zero, may represent a non-default state. In addition, the terms reset and set, in one embodiment, refer to a default and an updated value or state, respectively. For example, a default value potentially includes a high logical value, i.e. reset, while an updated value potentially includes a low logical value, i.e. set. Note that any combination of values may be utilized to represent any number of states.

The embodiments of methods, hardware, software, firmware or code set forth above may be implemented via instructions or code stored on a machine-accessible, machine readable, computer accessible, or computer readable medium which are executable by a processing element. A non-transitory machine-accessible/readable medium includes any mechanism that provides (i.e., stores and/or transmits) information in a form readable by a machine, such as a computer or electronic system. For example, a non-transitory machine-accessible medium includes random-access memory (RAM), such as static RAM (SRAM) or dynamic RAM (DRAM); ROM; magnetic or optical storage medium; flash memory devices; electrical storage devices; optical storage devices; acoustical storage devices; other form of storage devices for holding information received from transitory (propagated) signals (e.g., carrier waves, infrared signals, digital signals); etc., which are to be distinguished from the non-transitory mediums that may receive information there from.

Instructions used to program logic to perform embodiments of the present disclosure may be stored within a memory in the system, such as DRAM, cache, flash memory, or other storage. Furthermore, the instructions can be distributed via a network or by way of other computer readable media. Thus a machine-readable medium may include any mechanism for storing or transmitting information in a form readable by a machine (e.g., a computer), but is not limited to, floppy diskettes, optical disks, Compact Disc, Read-Only Memory (CD-ROMs), and magneto-optical disks, Read-Only Memory (ROMs), Random Access Memory (RAM), Erasable Programmable Read-Only Memory (EPROM), Electrically Erasable Programmable Read-Only Memory (EEPROM), magnetic or optical cards, flash memory, or a tangible, machine-readable storage used in the transmission of information over the Internet via electrical, optical, acoustical or other forms of propagated signals (e.g., carrier waves, infrared signals, digital signals, etc.). Accordingly, the computer-readable medium includes any type of tangible machine-readable medium suitable for storing or transmitting electronic instructions or information in a form readable by a machine (e.g., a computer).

### EXAMPLES

Illustrative examples of the technologies disclosed herein are provided below. An embodiment of the technologies may include any one or more, and any combination of, the examples described below.

Example 1 includes a photonic integrated circuit (PIC) die comprising a waveguide; a microresonator coupled to the waveguide; a first bias electrode and a second bias electrode, wherein the first bias electrode and the second bias electrode apply an electric field across a region of the microresonator when a voltage is applied across the first bias electrode and the second bias electrode; a first contact pad connected to the first bias electrode; a second contact pad connected to the second bias electrode; a first resistor connected to the first bias electrode and a third contact pad; and a second resistor connected to the second bias electrode and a fourth contact pad.

Example 2 includes the subject matter of Example 1, and wherein the first resistor is monolithically integrated into the PIC die, wherein the second resistor is monolithically integrated into the PIC die.

Example 3 includes the subject matter of any of Examples 1 and 2, and further including a first capacitor connected across the third contact pad and a fifth contact pad; and a second capacitor connected across the fourth contact pad and a sixth contact pad.

Example 4 includes the subject matter of any of Examples 1-3, and wherein the first capacitor is a metal-insulator-metal (MIM) capacitor that is monolithically integrated into the PIC die, wherein the second capacitor is an MIM capacitor that is monolithically integrated into the PIC die.

Example 5 includes the subject matter of any of Examples 1-4, and wherein the first contact pad, the second contact pad, the third contact pad, and the fourth contact pad are bumps to connect to a separate die.

Example 6 includes a system comprising the PIC die of Example 1, further comprising a driver; and a transmission line connecting the driver to the first contact pad and the second contact pad, wherein the first resistor and the second resistor are to terminate signals sent by the driver on the transmission line.

Example 7 includes the subject matter of Example 6, and wherein the driver is to transmit radiofrequency (RF) signals on the transmission line, wherein the RF signals cause the microresonator to modulate an amplitude of light in the waveguide.

Example 8 includes the subject matter of any of Examples 6 and 7, and further including a first voltage source connected to the third contact pad; and a second voltage source connected to the fourth contact pad, wherein the first voltage source and the second voltage source are to provide a DC bias to the microresonator.

Example 9 includes the subject matter of any of Examples 6-8, and wherein the transmission line is at least 25 millimeters long, wherein the driver is to send radiofrequency signals on the transmission line at a frequency of at least 40 gigahertz.

Example 10 includes a system comprising the PIC die of Example 1, the system further comprising a circuit board, wherein the PIC die is mounted on the circuit board, a first wire bond connecting the first contact pad to a first trace on the circuit board; a second wire bond connecting the second contact pad to a second trace on the circuit board; a third wire bond connecting the third contact pad to a third trace on the circuit board; and a fourth wire bond connecting the fourth contact pad to a fourth trace on the circuit board.

Example 11 includes a system comprising a photonic integrated circuit (PIC) die comprising a microresonator modulator; a driver to drive the microresonator modulator; and a transmission line connecting the driver to the microresonator modulator, wherein the PIC die comprises one or more resistors to terminate signals from the transmission line.

Example 12 includes the subject matter of Example 11, and wherein the one or more resistors are monolithically integrated into the PIC die.

Example 13 includes the subject matter of any of Examples 11 and 12, and wherein the one or more resistors comprise a first resistor and a second resistor, the system further comprising a first voltage source connected to the first resistor; and a second voltage source connected to the second resistor, wherein the first voltage source and the second voltage source are to provide a DC bias to the microresonator modulator.

Example 14 includes the subject matter of any of Examples 11-13, and wherein the transmission line is at least 25 millimeters long, wherein the driver is to send radiofrequency signals on the transmission line at a frequency of at least 40 gigahertz.

Example 15 includes the subject matter of any of Examples 11-14, and wherein the driver is to transmit radiofrequency (RF) signals on the transmission line, wherein the RF signals cause the microresonator modulator to modulate an amplitude of light in a waveguide coupled to the microresonator modulator.

Example 16 includes a system comprising a photonic integrated circuit (PIC) die comprising a microresonator modulator; a driver to drive the microresonator modulator; and a transmission line connecting the driver to the microresonator modulator, wherein the PIC die comprises a bias tee, wherein the transmission line is connected to one input of the bias tee, wherein a voltage source is connected to a second input of the bias tee, and wherein the bias tee is to terminate signals on the transmission line.

Example 17 includes the subject matter of Example 16, and wherein the bias tee comprises one or more resistors, wherein the one or more resistors are monolithically integrated into the PIC die.

Example 18 includes the subject matter of any of Examples 16 and 17, and wherein the bias tee comprises one or more resistors, wherein the one or more resistors comprise a first resistor and a second resistor, the system further comprising a first voltage source connected to the first resistor; and a second voltage source connected to the second resistor, wherein the first voltage source and the second voltage source are to provide a DC bias to the microresonator modulator.

Example 19 includes the subject matter of any of Examples 16-18, and wherein the transmission line is at least 25 millimeters long, wherein the driver is to send radiofrequency signals on the transmission line at a frequency of at least 40 gigahertz.

Example 20 includes the subject matter of any of Examples 16-19, and wherein the driver is to transmit radiofrequency (RF) signals on the transmission line, wherein the RF signals cause the microresonator modulator to modulate an amplitude of light in a waveguide coupled to the microresonator modulator.

Example 21 includes a system comprising a photonic integrated circuit (PIC) die comprising a microresonator modulator; a driver to drive the microresonator modulator; and a transmission line connecting the driver to the microresonator modulator, wherein the PIC die comprises means for terminating signals sent on the transmission line.

Example 22 includes the subject matter of Example 21, and wherein the PIC die comprises means for providing a DC bias to the microresonator modulator.

Example 23 includes the subject matter of any of Examples 21 and 22, and wherein the means for terminating signals sent on the transmission line comprises one or more resistors, wherein the means for providing the DC bias to the microresonator modulator comprise the one or more resistors.

1. A photonic integrated circuit (PIC) die comprising:
a waveguide;
a microresonator coupled to the waveguide;
a first bias electrode and a second bias electrode, wherein the first bias electrode and the second bias electrode apply an electric field across a region of the microresonator when a voltage is applied across the first bias electrode and the second bias electrode;
a first contact pad connected to the first bias electrode;
a second contact pad connected to the second bias electrode;
a first resistor connected to the first bias electrode and a third contact pad; and
a second resistor connected to the second bias electrode and a fourth contact pad.

2. The PIC die of claim 1, wherein the first resistor is monolithically integrated into the PIC die, wherein the second resistor is monolithically integrated into the PIC die.

3. The PIC die of claim 1, further comprising:
a first capacitor connected across the third contact pad and a fifth contact pad; and
a second capacitor connected across the fourth contact pad and a sixth contact pad.

4. The PIC die of claim 3, wherein the first capacitor is a metal-insulator-metal (MIM) capacitor that is monolithically integrated into the PIC die, wherein the second capacitor is an MIM capacitor that is monolithically integrated into the PIC die.

5. The PIC die of claim 1, wherein the first contact pad, the second contact pad, the third contact pad, and the fourth contact pad are bumps to connect to a separate die.

6. A system comprising the PIC die of claim 1, further comprising:
a driver; and
a transmission line connecting the driver to the first contact pad and the second contact pad,
wherein the first resistor and the second resistor are to terminate signals sent by the driver on the transmission line.

7. The system of claim 6, wherein the driver is to transmit radiofrequency (RF) signals on the transmission line, wherein the RF signals cause the microresonator to modulate an amplitude of light in the waveguide.

8. The system of claim 6, further comprising:
a first voltage source connected to the third contact pad; and
a second voltage source connected to the fourth contact pad,
wherein the first voltage source and the second voltage source are to provide a DC bias to the microresonator.

9. The system of claim 6, wherein the transmission line is at least 25 millimeters long, wherein the driver is to send radiofrequency signals on the transmission line at a frequency of at least 40 gigahertz.

10. A system comprising the PIC die of claim 1, the system further comprising:
a circuit board, wherein the PIC die is mounted on the circuit board,
a first wire bond connecting the first contact pad to a first trace on the circuit board;
a second wire bond connecting the second contact pad to a second trace on the circuit board;
a third wire bond connecting the third contact pad to a third trace on the circuit board; and
a fourth wire bond connecting the fourth contact pad to a fourth trace on the circuit board.

11. A system comprising:
a photonic integrated circuit (PIC) die comprising a microresonator modulator;
a driver to drive the microresonator modulator; and
a transmission line connecting the driver to the microresonator modulator,
wherein the PIC die comprises one or more resistors to terminate signals from the transmission line.

12. The system of claim 11, wherein the one or more resistors are monolithically integrated into the PIC die.

13. The system of claim 11, wherein the one or more resistors comprise a first resistor and a second resistor, the system further comprising:
a first voltage source connected to the first resistor; and
a second voltage source connected to the second resistor,
wherein the first voltage source and the second voltage source are to provide a DC bias to the microresonator modulator.

14. The system of claim 11, wherein the transmission line is at least 25 millimeters long, wherein the driver is to send radiofrequency signals on the transmission line at a frequency of at least 40 gigahertz.

15. The system of claim 11, wherein the driver is to transmit radiofrequency (RF) signals on the transmission line, wherein the RF signals cause the microresonator modulator to modulate an amplitude of light in a waveguide coupled to the microresonator modulator.

16. A system comprising:
a photonic integrated circuit (PIC) die comprising a microresonator modulator;
a driver to drive the microresonator modulator; and
a transmission line connecting the driver to the microresonator modulator,
wherein the PIC die comprises a bias tee, wherein the transmission line is connected to one input of the bias tee, wherein a voltage source is connected to a second input of the bias tee, and wherein the bias tee is to terminate signals on the transmission line.

17. The system of claim 16, wherein the bias tee comprises one or more resistors, wherein the one or more resistors are monolithically integrated into the PIC die.

18. The system of claim 16, wherein the bias tee comprises one or more resistors, wherein the one or more resistors comprise a first resistor and a second resistor, the system further comprising:
a first voltage source connected to the first resistor; and
a second voltage source connected to the second resistor,
wherein the first voltage source and the second voltage source are to provide a DC bias to the microresonator modulator.

19. The system of claim 16, wherein the transmission line is at least 25 millimeters long, wherein the driver is to send radiofrequency signals on the transmission line at a frequency of at least 40 gigahertz.

20. The system of claim 16, wherein the driver is to transmit radiofrequency (RF) signals on the transmission line, wherein the RF signals cause the microresonator modulator to modulate an amplitude of light in a waveguide coupled to the microresonator modulator.
